(19) United States
(12) Patent Application Publication
(10) Pub. No.: US 2005/0205412 A1
(43) Pub. Date: Sep. 22, 2005

(54) Sputtering device for manufacturing thin films

(76) Inventors: Hartmut Rohrmann, Mels (CH); Jens Baumann, Chemnitz (DE)

Correspondence Address: PEARNE & GORDON LLP, 1801 EAST 9TH STREET, SUITE 1200, CLEVELAND, OH, 44114-3108, US

(21) Appl. No.: 11/085,766

(22) Filed: Mar. 21, 2005

Related U.S. Application Data
(60) Provisional application No. 60/555,101, filed on Mar. 22, 2004.

(51) Int. Cl. C23C 14/35

(52) U.S. Cl. 204/192.12; 204/298.19; 204/298.16; 204/298.11

(57) ABSTRACT

A sputtering station for depositing a thin film on a substrate includes a cathode comprising two targets placed opposite each other defining a plasma region, permanent magnets or coils to generate a magnetic field, yokes to direct the magnetic field and two independent power supplies connected to each target to independently control the energy to each target.

### FIELD OF INVENTION

The invention relates to a device for manufacturing thin films through a method of sputtering having two facing targets in a cathode and positioning a substrate in a plane essentially parallel to the planes of the facing targets.

### BACKGROUND OF THE INVENTION

Sputter coating stations consisting of one or more targets and a substrate arranged in a vacuum vessel filled with sputter gas are known to work on two basic principles: In the first principle the plasma is confined by magnetic field lines form a tunnel over the surface of each target. This tunnel forms a closed loop on the target surface. The accelerating electric fields at the cathode dark space are directed perpendicular to the sputtering surfaces of each target. Presently moving magnet systems are commonly used to scan the surface of the target to be sputtered, especially for circular targets. In the second principle the magnetic field is perpendicular to the sputtering surfaces of each target. The plasma is confined in the space between the targets by the magnetic field. The electric fields at the cathode dark space are directed perpendicular to the sputtering surfaces of each target and thus parallel to the magnetic field. The present invention operates according to the second principle.

U.S. Pat. No. 4,407,894 describes a method according to the second principle for producing a cobalt chromium alloy layer. The magnetic field is generated by permanent magnets or a DC powered coil. The electric fields are generated by either a DC or RF power source connected to the target (cathode) and shields (anode).

In U.S. Pat. No. 5,000,834 the preparation of alloyed films of different composition is claimed. The two targets are made of materials different from each other. Each target is connected to a separate variable AC or DC power source(s) that can be controlled independentlyf each other. The film composition on the substrate adjacent to the plasma region is set by varying the power applied to the targets. The plasma confinement and thus the target erosion depend on strength and homogeneity of the magnetic field between the targets. A disadvantage of this device is that a strong and homogeneous magnetic field at the target surfaces is difficult to achieve especially for permanent magnets and nonmagnetic target materials. While the placement of the substrate outside the plasma region reduces radiation damage and heating, a uniform thickness distribution is difficult to achieve especially for non-rotating substrates. In addition, deviations in composition are to be expected if alloyed films are deposited using targets of different materials.

U.S. Pat. No. 4,690,744 describes an ion beam generator comprising a plurality of opposing targets. Ionized particles are generated by sputtering the targets. The ionized particles are extracted through small holes in at least one target and form a film on a substrate behind the target.

U.S. Pat. No. 5,753,089 describes a sputter coating station for a double-sided coating where the substrate is placed between the targets during the deposition process. At least one of the opposed targets has a clear opening through which a substrate mounting arrangement can move a substrate between the targets.

Prior Art devices operating in accordance with the second principle generate the magnetic field by permanent magnets located on the back portion of the targets or by DC powered coils having a diameter larger than the diameter of the target. The permanent magnets and coils are usually located outside the vacuum. One object of the present invention is to guide the magnetic field to the back portion of the targets using yokes made of high saturation magnetization materials. This allows the magnetic field generation sources to be re-positioned without losing the functionality of the device. For example, the permanent magnets or coil can be positioned between the targets in air or in vacuum and thus the magnetic flux can reach the back portion of the targets. Alternatively, if permanent magnets are no longer necessary on the back portion of the targets a substrate can be positioned there under vacuum. The deposition of the substrate with sputtered material is possible through a hole in the target close to the substrate.

Another advantage of the present invention is that while conventional magnetron sputtering of magnetic targets according to the first principle is difficult for magnetic materials the functionality of the present invention is not limited by the thickness or permeability of magnetic targets.

Still yet another advantage of the present invention is that multilayered films can be prepared by modulation of the power ratios between the targets during the deposition process.

### BRIEF SUMMARY OF THE INVENTION

In accordance with one aspect of the present invention a sputter cathode is provided comprising a plurality of opposing targets, a plasma region located between the plurality of opposing targets, a magnetic field generating source adjacent the opposing targets, said field extending over a major part of the plasma region essentially perpendicular to the surface of the opposing targets where a substrate is positioned adjacent to the plasma region and where at least one target includes an opening such that deposition of a film on the substrate is not impeded by the target and where the vertical planea of the opposing targets and the vertical plane of the substrate are substantially parallel. Said source may be positioned around the perimeter of the cathode and comprise a plurality of yokes to thereby guide the magnetic field to the back portion of the targets.

In accordance with yet another aspect of the present invention a sputter station is provided comprising a first and second sputter cathode where both the first and second sputter cathode include a plurality of opposing targets, a plasma region located between the plurality of opposing targets, a magnetic field generating source positioned around the the cathode, where at least one target includes an opening such that deposition of a film on a substrate is not impeded by the target and where the vertical plane of the at least one ring and the vertical plane of the substrate are substantially parallel.

### BRIEF DESCRIPTION OF THE DRAWINGS

FIG. 1 is a schematic cross section of a minimum configuration of a cathode according to the invention, if realized using permanent magnets.

FIG. 2 is a schematic of an alternative embodiment of a coating station comprising two cathodes.

FIG. 3a is an illustration of the resulting orientation of the magnetic flux density in a coating station consisting of two cathodes with unidirectional orientated magnetization vectors of the permanent magnets.

FIG. 3b is an illustration of the resulting orientation of the magnetic flux density in a coating station consisting of two cathodes with anti-parallel orientated magnetization vectors of the permanent magnets.

FIG. 4 represents the effect of the magnetic field delivered by the permanent magnets on the magnetic flux density for an embodiment according to FIG. 3b.

FIG. 5 is an illustration of the current voltage characteristics of glow discharges ignited in the cathode for different argon pressures.

FIG. 6 is a diagram showing, how the deposition rate of iron—measured at a substrate radius of 20 mm—depends on the argon pressure and on the ratio of the power applied to the main and to the auxiliary target.

FIG. 7 is a graph showing the adjustability of the film thickness distribution by changing the potential of the ring anode and by changing the argon pressure.

FIG. 8 illustrates the erosion profiles of an annular main target of iron, resulting from sputtering with the ring anode being on ground or at floating potential.

### DETAILED DESCRIPTION OF THE PREFERRED EMBODIMENTS OF THE INVENTION

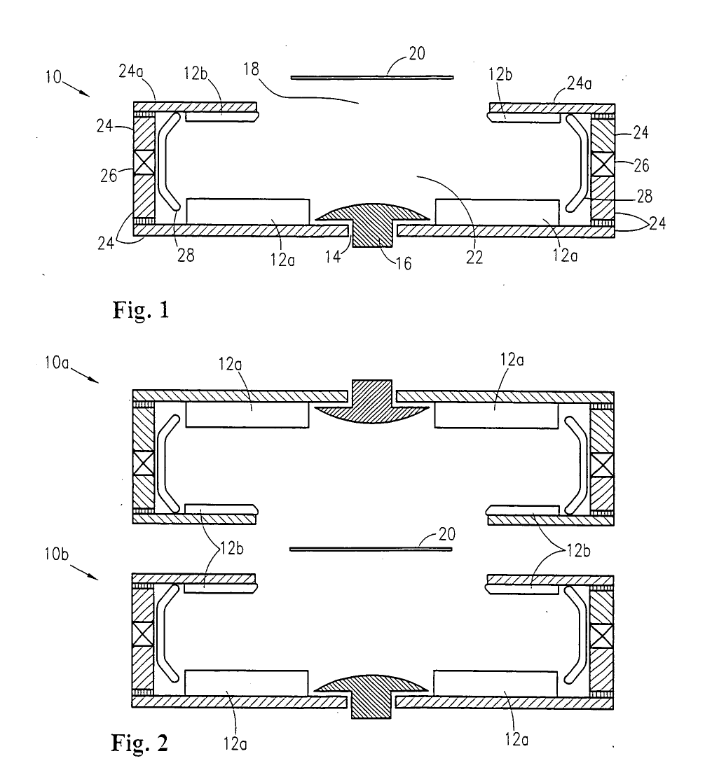

FIG. 1 shows a cathode 10 comprising a main 12a and an auxiliary 12b target that are arranged face to face in a vacuum vessel. The target surfaces can be either planar and parallel to each other or may have a conical shape. Further, the area of the each targets 12a, 12b, given by their inner and/or outer diameter, may be different. Each target 12a, 12b is connected to a separate DC, pulsed DC or RF power source. The main target 12a includes an opening 14 that may contain a center anode 16. The center anode 16 may be grounded, biased or left floating. The auxiliary target also includes an opening 18 to allow a sputter material, described further below, to pass to a substrate 20. At least one of the targets 12a, 12b may be manufactured of a magnetic material and as such the target will carry and homogenize the magnetic flux by acting as an extended yoke 24 or a pole piece. The targets can be made from any material known in the art such as iron. It should be noted that the shape of the targets 12a, 12b of the present invention can be any shape known in the art such as round, annular, angular, longitudinal, frame, etc. A plasma region 22 is located between the main 12a and auxiliary 12b targets.

The cathode 10 further includes permanent magnets or coils 26 that generate a magnetic field. The magnets or coils 26 are arranged in one or more rings around the perimeter of the cathode 10 and not on the back portion (the side of the targets not facing each other) of the targets 12a, 12b. Further, the inner diameter of the ring(s) is larger than the outer diameter of the both the main 12a and the auxiliary 12b targets. The rings are positioned such that the vertical plane of the ring(s) is positioned between the vertical plane of the targets 12a, 12b and the rotational axes of the targets 12a, 12b and the rings are identical in direction. As a result, the magnetization of the permanent magnets 26 is parallel to the rotational axis of the rings. A portion of the magnet rings or coils 26 can be used as an electrode and can be grounded, biased or left floating. The width of the magnet rings or coils 26, measured in a plane essentially parallel to the targets is called r_{mag}, in other words, the “thickness” of the coil 26.

The cathode 10 further comprises multiple yokes 24 made of magnetic material that are arranged to guide the magnetic field to the back portion of main 12a and auxiliary 12b targets. The magnetic flux generated by the permanent magnets or the coils 26 passes the yokes 24, the main target 12a, through a plasma region 22, passes the auxiliary target 12b and is guided back to the permanent magnets or coils 26 by the yoke 24. The portion of yoke 24a closest to the substrate 20 can be designed in such a way to obtain a specific radial configuration of the magnetic stray field outside the cathode 10. The yokes can be made from any material known in the art such as iron. A portion of the yoke 24 can be used as an electrode and can be grounded, biased or left floating.

A shield 28 may be added to separate both the yoke 24 and magnets or coils 26 from the targets 12a, 12b to thereby protect the yoke 24 and the magnets or coils 26 from being deposited during the sputtering process. A portion of the shield 28 can be grounded, biased or left floating and as such will act as a ring anode.

The substrate 20 is placed adjacent to a plasma region 22 and in front of the opening 18. The substrate 20 can be grounded, biased or left floating. In operation, the targets 12a, 12b are sputtered with a sputter material such as a noble gas such as argon, krypton, etc. Material particles are generated as a result of the sputtering process and are directed through the opening 18 by the magnetic field and deposited on the substrate 20 to thereby form a thin film on the substrate 20. Thus, the opening 18 is of a suitable size where deposition of the substrate 20 is not impeded by the target 12b. In this embodiment the substrate 20 is coated on one side with a thin film.

FIG. 2 shows an alternative embodiment of the present invention comprising a first 10a and second 10b cathode. The first 10a and second 10b cathodes are the same as the cathode 10 described above and will not be repeated. In this embodiment the first 10a and second 10b cathodes face each other such that the openings 18 of the auxiliary targets 12b are adjacent to each other. The substrate 20 is placed between the cathodes 10a, 10b in front of the openings 18 and adjacent to the plasma regions 22 of each cathode 10a, 10b as shown in FIG. 2. In this embodiment, during the sputtering process the substrate 20 is coated on both sides with a thin film.

The strength and homogeneity of the magnetic field between the targets 12a, 12b can be varied by several methods such as, using permanent magnet(s) of different remanence, or using magnet rings of different radial dimension (r_{mag}) as shown in FIG. 4, or by varying the current through the coils, or by changing the permeability of the magnetic materials for the yokes, or by realizing different yoke geometries by varying the inner or outer diameter as well as thickness of the yoke. For example, the strength and direction of the magnetic field can be modified by a radial thickness change of the yoke plate. Further, the magnetic field configuration generated by the magnets influences the plasma confinement between the targets and thus can be used to improve the thickness uniformity of the deposited films.

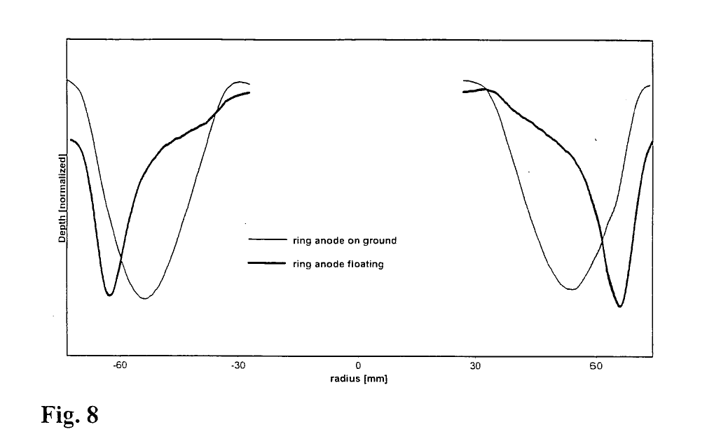

Further, the thickness uniformity of the deposited films can be controlled by adjusting the potentials of the ring anode, the center anode or the yoke, thus modulating the plasma density as shown in FIG. 7. The modulation of the plasma density enables the control of the radial erosion profile of the targets as shown in FIG. 8.

If the targets 12a, 12b are made from different materials the ratio of the target areas as well as the ratio of the power applied to each target can be used to change the composition ratio of a deposited film. Preferred material are in general, but not limited to, ferromagnetic materials. Adding nitrogen, oxygen or other elements to the noble sputter gas (argon, krypton, etc.) will further influence the film composition. If the targets 12a, 12b are made from the same material the ratio of the power applied to each target can be used to control thickness uniformity. The power ratio can also be used to minimize the erosion of the auxiliary target, thus the auxiliary target can be much smaller than the main target but both targets will have the same lifetime. As a result, the thickness of the auxiliary target 12 can be significantly reduced as compared to the main target 12a.

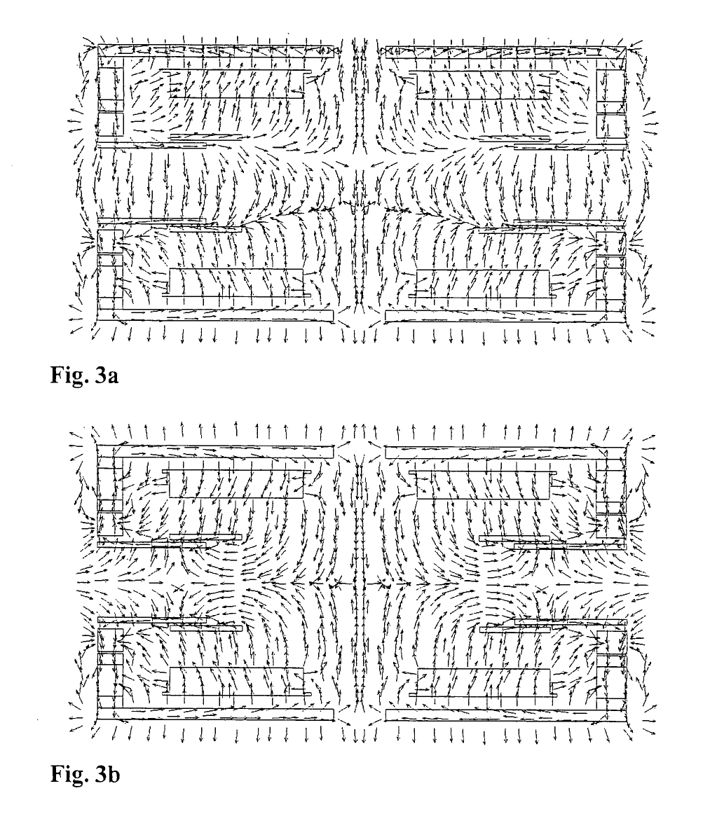

The magnetic stray field of the yoke portions 24a closest to the substrate 20 influence the textural, structural, and magnetic properties of the growing film. The magnetic field near the substrate 20 determines the electron bombardment to the substrate 20 and the preferred orientation of the deposited magnetic films. For example, in the second embodiment where two cathodes 10a, 10b are used for a symmetric double-sided coating of one substrate 20 the configuration of the resulting magnetic field depends on the direction of the magnetization vector of the permanent magnets 26. As shown in FIG. 3a the magnetization vectors are unidirectional and thus, the magnetic field influences the texture of the growing film. Magnetic field components perpendicular to the substrate 20 surface also result in an increased electron bombardment. As a result, the substrate 20 is heated and a bias potential will build up for a floating substrate. As shown in FIG. 3b the magnetization vectors are anti-parallel and thus the radial component of the magnetic field influences the texture of the growing film. The magnetic field components perpendicular to the substrate 20 are small or nearly zero. The electrons are guided along the field lines in radial direction and surpass the substrate 20. As a result, the heating or biasing by electron bombardment is suppressed. Alternatively, operating independent from the magnetization vectors an additional magnetic field can be overlaid by a DC powered coil. The coil can be larger than the substrate and the planes of coil and substrate 20 are preferably parallel. In this example the axial component of the magnetic field will guide electrons to the substrate 20 that will in turn heat the substrate resulting in a build up of a bias potential for a floating substrate.

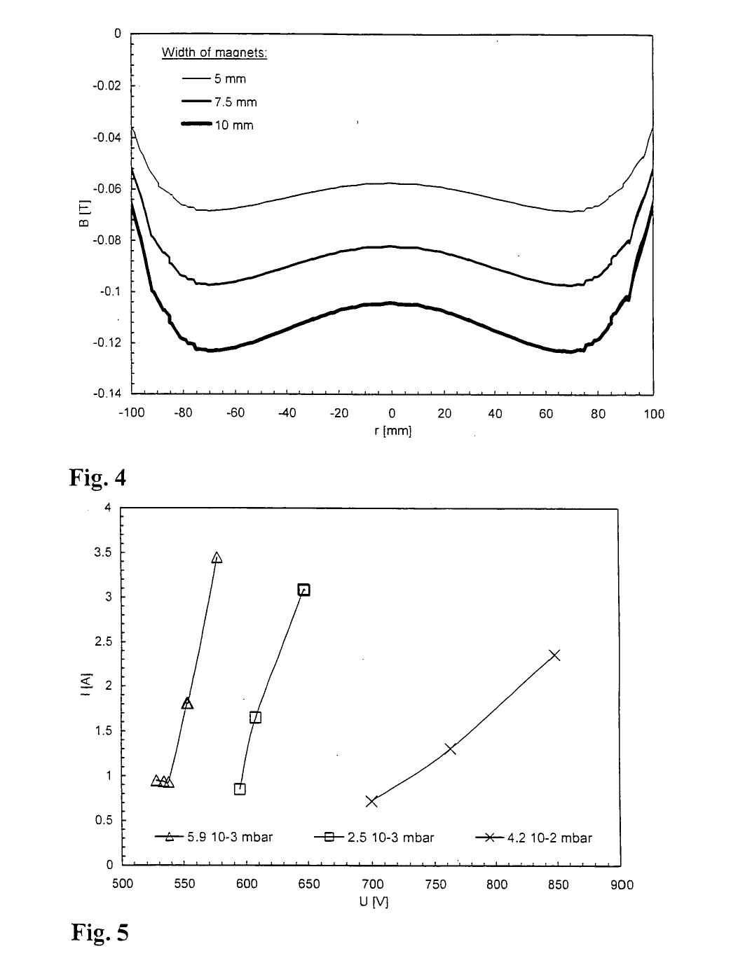

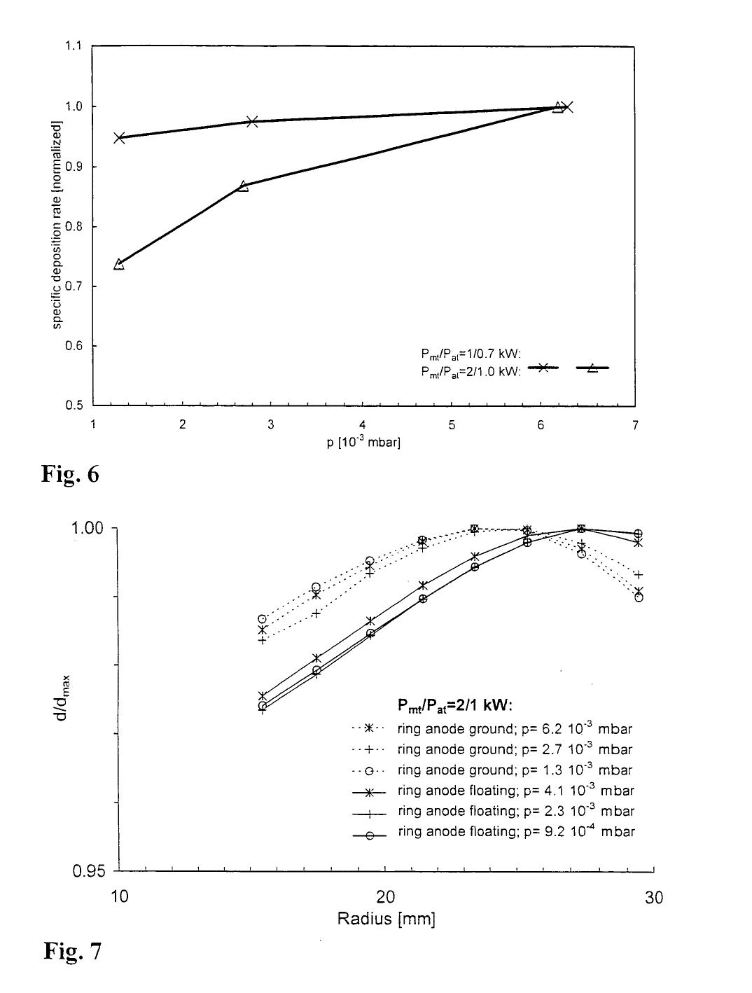

The present invention was tested in the pressure range between 2·10⁻⁴ mbar and 6·10⁻² mbar in argon. Stable glow discharges can be ignited within this pressure range as shown in the current voltage characteristics in FIG. 5. The deposition rate for iron is between 2.5 nm/kW/s and 4.5 nm/kW/s for a distance of 50 mm between main target 12a and substrate 20. This deposition rate is normalized to the power applied to the main target 12a. With a constant power level Pₘₜ applied to the main target 12a a decrease of the power Pₐₜ applied to the auxiliary target 12b results in a decreased deposition rate as shown in FIG. 6. Further, the deposition rate will reach its maximum if the power applied to the main 12a and auxiliary 12b targets is equal. For a constant power applied to one target the glow discharge will vanish if the power applied to the opposing target falls below a certain threshold value. As shown in FIG. 6, increasing the argon pressure will increase deposition rate where a constant distance between the cathode and substrate 20 is maintained.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A sputter cathode comprising:
a plurality of opposing targets;
a plasma region located between the plurality of opposing targets;
a magnetic field generating source positioned adjacent the opposing targets, said field extending over a major part of the the plasma region essentially perpendicular to the surface of the opposing targets;
wherein a substrate is positioned adjacent to the plasma region;
wherein at least one target includes an opening such that deposition of a film on the substrate is not impeded by the target,
wherein the vertical planes of the opposing targets and the vertical plane of the substrate are substantially parallel.

2. The sputter cathode of claim 1, wherein the magnetic field generation source comprises at least one ring of a magnetic field generating source positioned around the perimeter of the cathode; and,
a plurality of yokes to thereby guide the magnetic field to the back portion of the targets where the back portion is the side of each target not facing each other.

3. The sputter cathode of claim 1, wherein the magnetic field generating source is one of a permanent magnet or a coil.

4. The sputter cathode of claim 3 further comprising:
a shield separating the yokes and coil from the plurality of targets, wherein the shield is a ring anode; and,
a center anode positioned in an opening in a second target.

5. The sputter cathode of claim 4, wherein the film thickness uniformity and erosion of the plurality of targets are influenced by adjusting the potential of one of the yokes, center anode or ring anode.

6. The cathode of claim 4 further comprising a first power source connected to one opposing target and a second power source connected to a second opposing target, wherein the film composition can be varied by one of adjusting the first power source, adjusting the second power source, or adjusting both the first and second power sources.

7. The sputter cathode of claim 6, wherein the film composition can be varied by adjusting the area of the opposing targets.

8. The sputter cathode of claim 7, wherein the film thickness uniformity can be varied by one of adjusting the first power source, adjusting the second power source, or adjusting both the first and second power sources.

9. The sputter cathode of claim 8, wherein the plurality of targets are one of circular, annular, angular, longitudinally extended or framed shaped.

10. The sputter cathode of claim 9, wherein the plurality of targets are made of the same material.

11. The sputter cathode of claim 9, wherein the plurality of targets are made from different materials.

12. The sputter cathode of claim 6 further comprising a sputter gas comprising a noble gas.

13. The sputter cathode of claim 12, wherein the film composition can be varied by adding one of nitrogen, oxygen or other element to the sputter gas.

14. The sputter cathode of claim 13, wherein the sputter rate for the sputter gas can be varied by one of adjusting the first power source, adjusting the second power source, or adjusting both the first and second power sources

15. The sputter cathode of claim 14, wherein the magnetic field outside the cathode is varied by adjusting the geometry of the yokes and wherein the texture, structure and magnetic properties of the film are influenced by the magnetic field outside the cathode.

16. A sputter station comprising:
a first and second sputter cathode where both the first and second sputter cathode include:
a plurality of opposing targets;
a plasma region located between the plurality of opposing targets;
a magnetic field generating source adjacent the opposing targets, said field extending over a major part of the the plasma region essentially perpendicular to the surface of the opposing targets;
wherein at least one target includes an opening such that deposition of a film on a substrate is not impeded by the target,
wherein the plane of the opposing targets and the plane of the substrate are substantially parallel.

17. The sputter station of claim 16, wherein the substrate is positioned between the first and second cathodes and adjacent to the plasma regions and is coated on both sides with a thin film.

18. The sputter station of claim 17, wherein the magnetization vectors of the magnetic field outside the cathode are unidirectional and perpendicular to the substrate.

19. The sputter station of claim 17, wherein the magnetization vectors of the magnetic field outside the cathode are oppositely aligned and parallel to the substrate.

20. The sputter station of claim 16, wherein the magnetic field generation source comprises at least one ring of a magnetic field generating source positioned around the cathode; and,
a plurality of yokes to thereby guide the magnetic field to the back portion of the targets.

21. A method for producing thin films comprising the steps of:
providing a sputter cathode having a plurality of opposing targets wherein at least one target has an opening, a plasma region located between the plurality of opposing targets, at least one ring of a magnetic field generating source positioned around the perimeter of the cathode, and a plurality of yokes to thereby guide the magnetic field to the back portion of the targets where the back portion is the side of each target not facing each other;
positioning a substrate adjacent to the plasma region;
generating plasma in the plasma region;
sputtering the targets with the plasma thereby generating ionic particles;
directing the ionic particles through the hole; and,
depositing the particles on the substrate to form a thin film.
